(19) United States
(12) Patent Application Publication
(10) Pub. No.: US 2021/0173307 A1
(43) Pub. Date: Jun. 10, 2021

(54) HIGH-RESOLUTION FLEXOGRAPHIC PRINTING PLATE WITH IMPROVED BARRIER LAYER AND ADHESION MODULATING LAYER AND MEANS FOR ITS PRODUCTION

(71) Applicant: FOLEX AG, Seewen (CH)

(72) Inventors: François Varescon, Brunnen (CH); Carlfried Osenegg, Küssnacht am Rigi (CH); Robert Nigg, Gersau (CH); Daniel Sutter, Walchwil (CH)

(73) Assignee: FOLEX AG, Seewen (CH)

(21) Appl. No.: 17/110,447

(22) Filed: Dec. 3, 2020

(30) Foreign Application Priority Data
Dec. 6, 2019 (EP) 19 214 306.3

(51) Int. Cl. G03F 7/20; B41C 1/055; G03F 7/021; G03F 7/085; G03F 7/095

(52) U.S. Cl. CPC G03F 7/202; B41C 1/055; G03F 7/095; G03F 7/085; G03F 7/021

(57) ABSTRACT

Described is a recording element which is suitable for the production of high-resolution flexographic printing plates by means of digital information transmission that can be imaged with actinic laser radiation and comprises or consists of the following layers:
(A) a carrier film,
(B) a photopolymerizable layer/relief forming polymer layer which is cross-linkable by actinic radiation,
(C) an actinic radiation transparent intermediate layer composite, comprising at least two polymer comprising composite layers lying on top of each other, a first composite layer (C1) acting as blocking layer or barrier layer and a second composite layer (C2) acting as adhesion modulator against the relief forming polymer layer,
(D) a recordable template layer comprising a monomeric diazonium compound, and
(E1) optionally a peelable protective film or cover film on the recordable template layer (D).

### CROSS REFERENCES TO RELATED APPLICATIONS

This application claims the priority of European patent application 19 214 306.3, filed Dec. 6, 2019, the disclosure of which is incorporated herein by reference in its entirety.

### FIELD OF THE INVENTION

The invention relates to recording elements for the production of high-resolution flexographic printing plates, which are suitable for digital information transmission, as well as means for their production and methods for producing high-resolution flexographic printing plates, said recording means having an intermediate layer with improved features between a relief forming polymer layer and a recordable template layer.

### BACKGROUND

Recording elements for recording digital information are known in principle. They consist—for the production of conventional flexographic printing plates—of at least one carrier, a photopolymerizable layer as well as a layer capable of recording digital information (recordable template).

The recordable template layer may be, for example, a photopolymer-based layer (see EP 0797120 A2 and EP 0913730 B1), an ink jet-printable layer (see U.S. Pat. No. 7,875,321 B2), a thermographic layer (see DE60125755 T2, US2014370440 AI and US2003/211423 A1), a silver halide emulsion layer or a laser-ablatable layer (see US2008258344 A1, WO2015040094 A2, WO 2016188981 A1), the type of recordable layer being responsible for the quality of the reproduction of the low and high tonal values of the printed products.

The layer of digital flexographic printing plates that is crucial for the print is the photopolymerizable layer arranged on a carrier (usually a film of polyethylene terephthalate (PET)). Below, this photopolymerizable layer is also referred to as relief-forming polymer layer, since it results in the final printing plate profile after the washing out/leaching process. In the preparation of the printing plate profile, the recordable layer plays an important role, since it is responsible for the resolution of the printing plate profile. Among other things, this resolution comprises the reproduction of the fine print elements and the low and high tonal values, in particular in the range of 0 to 5% or 95 to 100% of the screen dots.

The above-mentioned methods with a recordable layer based on an ink-jet printable layer, a thermographic layer or a laser-ablatable layer (also referred to as LAMS (laser ablatable mask layers)) do not show the desired printing results with respect to the reproduction of the fine print elements and the low and high tonal values in the range of 0-5% and 95-100% of the screen dots at high resolution (80 lines/cm, 4400 dpi).

In addition, the exposure technologies used to make the printing plates require two different exposure units, which are an important cost factor in plate making. In addition, during the exposure processes, oxygen attack occurs, which is enhanced by double exposure.

From EP 0 797 120 A2, the use of a recordable layer based on a photopolymer is known. This layer consists of an arylazophosphonate comprising compound of formula

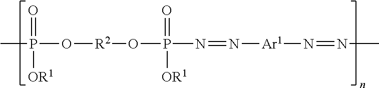

wherein R¹, R², Ar¹ and n have the meaning given in EP 0 797 120 A2, pages 5 and 6.

By exposure by means of actinic laser radiation, the layer having an optical density in the actinic region of >2.5 undergoes a change in the optical density of >1 at the exposed areas under high energy values of >5 up to 50 J/cm².

After exposure or crosslinking, the recordable template layer and the non-crosslinked parts of the relief forming polymer layer can be removed by means of one or more developers.

Such a recording material shall have the same properties as a recording material according to the comparative example.

A material according to EP 0 797 120 A2 shows the following problems:

The arylazophosphonate containing compounds may be monomeric or oligomeric (n=1 to 10) compounds. In particular, such oligomeric compounds as part of an ablatable layer can be destroyed only with the absorption of high UV radiation (<320 nm). This requires the use of expensive excimer lasers e.g. a XeCl laser (wavelength: 308 nm).

In addition, layers containing arylazophosphonate-containing polymers are unstable and age very rapidly.

Patent application EP 3 401 732 A1 describes a recordable template layer comprising a monomeric diazonium compound that is sensitive to actinic laser radiation as a component of a recording element for the production of a digitally imageable flexographic printing plate. The high resolution of the screen dots below the low and above the high tonal values in the range of 0-5% and/or 95-100% i.a. is achieved by means of a thin film or an intermediate layer below 20 μm. The intermediate layer shortens the imaging and cross-linking processes and greatly reduces the oxygen attack during the exposure process.

Unfortunately, the product or the process used, respectively has limitations in the production of the semi-finished product made of film (C) and recordable template layer (D) or the use of the semi-finished product in the production of digitally imageable printing plates. In the case of very thin intermediate films (thickness<20 μm) wrinkles formation, poor dimensional stability and therefore uneven transfer and uneven lamination to the relief-forming polymer layer occurs. In other words, an intermediate film with a thickness of less than 20 μm and with thereon applied recordable template layer has very poor processability or results in a suboptimal product, respectively.

The use of an intermediate layer (C) of a polymer like polyvinyl butyral (PVB) or polyvinyl alcohol as binder, that is disclosed in EP 3 401 732 A1 as an alternative to the thin film, is of only moderate suitability. No wrinkles are formed but diffusion of the diazo compound from the recordable template layer into the relief forming polymer layer and—in opposite direction—of the monomers from the relief-forming layer into the template layer was observed which clearly affects the stability of the printing plate upon aging.

Therefore, the object of the present invention was to provide a recording material suitable for the production of high-resolution flexographic printing plates with an improved adhesion modulating layer as intermediate layer, said recording material being suitable for digital information transmission and fulfilling at least one, preferably several, in particular all of the following subtasks a) to g):

a) The resolution of the screen dots below the low and above the high tonal values in the range of 0-5% and/or 95-100% is improved (in comparison to patent application EP 3 401 732 A1). This resolution exceeds the resolution obtainable with conventional plates, known at the end of 2018, for example plates sold by Dupont under the designation Cyrel® Now or FDT, using conventional silver halide methods, or laser ablatable (LAMS) layers such as Nyloflex® ACE 170 Digital from Flint, CYREL® DSP/DPN from Dupont or Digital LUX-ITP from Mac Dermid.

b) The imaging and crosslinking processes are shortened in terms of time.

c) The oxygen attack during the exposure process is significantly reduced, wherein no additional aid, such as nitrogen atmosphere, is needed.

d) After UV-irradiation and before the washing out/leaching process, the recordable template layer and the intermediate layer with good barrier properties shall be easily removable without damaging the surface of the UV-irradiated printing plate.

e) The production of the semi-finished product (film and recordable template layer) used in the production of the digitally imageable printing plate is improved by the uniformity of the lamination and the elimination of the wrinkles.

f) Good aging resistance of the recording element

g) No laser generating very short-wave laser radiation (<320 nm) is needed.

### DESCRIPTION OF THE INVENTION

At least one, in particular all of the above-mentioned subtasks are solved by providing a recording element that except for the intermediate layer or intermediate film, respectively, is identical with those of EP 3 401 732 A1 and the intermediate layer of which is an intermediate layer composite of at least two layers lying on top of each other, wherein a second composite layer is an adhesion modulating layer lying on the relief forming polymer layer and a first composite layer is a barrier layer for the diazonium compound comprised in the recordable template layer arranged between the second composite layer and the recordable template layer.

Such an actinic radiation transparent intermediate layer composite has the following main functions:

a) On the one hand the clean separation of the relief-forming polymer layer (B) from the recordable template layer (D), i.e. the prevention of diffusion between the layers. The diffusion of monomers and additives comprised in the relief-forming polymer layer (B), affect the stability of the recordable layer (D) and its resolution.

b) On the other hand the easy removal of the imaged template layer (D) with the intermediate layer composite (C) from the relief-forming polymer layer (B) after exposure of the recording element with actinic radiation through the imaged template layer. It has been found that a mere intermediate layer, e.g. of polyester or co-polyester prevents diffusion but cannot be peeled off the relief-forming polymer layer (B).

In general the actinic radiation transparent intermediate layer compound (C) has a thickness of up to 100 μm, like 0.1 μm to 100 μm, preferably from 0.2 μm to 50 μm, in particular from 0.4 μm to 30 μm, especially preferred from 0.6 μm to 20 μm, like 8 μm.

Although thin intermediate layer composites are preferred, also thicker composites often have advantages compared to films, e.g. better resolution since the layers have been applied one on top of the other as liquids resulting in intimate contact between the layers.

The actinic radiation transparent intermediate layer composite (C) in general consists of two separate polymer comprising layers. The first composite layer (C1) as blocking layer acts as barrier layer that is in direct contact with the recordable template layer (D). The first composite layer (C1) does not only prevent migration and/or diffusion of preferably all components comprised in the template layer (D) into the second composite layer (C2) and the relief forming polymer layer (B) but it also prevents subsequent diffusion of oxygen into the relief-forming polymer layer (B). The second layer (C2) arranged on top of the relief-forming polymer layer can easily be removed mechanically once the exposure processes are terminated.

Such an intermediate layer composite is in particular suitable in combination with a recordable template layer based on diazonium compounds that are sensitive to actinic laser radiation. Such a recordable template layer (D) together with an intermediate layer composite (C) may be part of a semi-finished product for the production of a recording material or the recordable template layer (D) and the intermediate layer composite (C) can be part of a recording element which comprises all layers necessary for the production of a flexographic printing plate. These layers are, in particular, a carrier (A), a conventional photopolymer layer (B) which can be crosslinked by actinic radiation and which is also referred to as a relief-forming polymer layer, a polymer-containing intermediate layer composite (C), a template layer (D) recordable by means of digital processes and based on diazonium compounds, and a protective film (E1) applied to the layer (D).

In particular, in one aspect, the present invention relates to a recording element which is suitable for the production of high-resolution flexographic printing plates by means of digital information transmission that can be imagined with actinic laser radiation, which comprises or consists of the following layers arranged one above the other in the stated sequence:

(A) a carrier film, in particular a plastic film, which may optionally be provided with an adhesive layer on the side provided with a photo-polymerizable layer/relief-forming polymer layer,

(B) a photopolymerizable layer/relief-forming polymer layer which is soluble in organic solvents and/or aqueous solvents and/or liquid or volatile due to heating and which is cross-linkable by actinic radiation,

(C) an actinic radiation transparent intermediate layer composite, comprising at least two polymer comprising composite layers lying on top of each other, wherein a second composite layer (C2) is an adhesion modulating layer lying on top of the relief forming polymer layer and a first composite layer (C1) is a barrier layer for the diazonium compounds comprised in the recordable template layer (D), said first composite layer (C1) being positioned between the second composite layer (C2) and the recordable template layer (D),

(D) a recordable template layer comprising a monomeric diazonium compound which is photosensitive to actinic laser radiation and undergoes a change in actinic density by development or an imaged template layer in which the monomeric diazonium compound is destroyed by actinic laser radiation in at least an area and has an increased actinic density in at least one unexposed area due to development.

In an embodiment, the inventive recording element additionally has

(E1) a peelable protective film or cover film arranged on the recordable template layer (D). Such a protective film or cover film shall be light-tight (actinically tight) for protecting the monomeric diazonium compound comprised in the recordable template layer (D) and can be made of plastic or paper or composite materials.

In a second aspect, the invention relates to a semi-finished product for the production of a recording element, as described above. This comprises

(E1) a peelable, preferably light-tight (actinically tight) protective film or cover film also serving as carrier

(D) a recordable template layer comprising a monomeric diazonium compound which is photosensitive to actinic laser radiation and which undergoes a change in actinic density by means of development.

(C) an intermediate layer composite that is transparent for actinic radiation and that comprises at least 2 polymer comprising composite layers laying on top of each other, wherein a second composite layer (C2) is an adhesion modulating layer arranged on top of the relief forming polymer layer and a first composite layer (C1) is a barrier layer for the diazonium compounds comprised in the recordable template layer (D), said first composite layer (C1) being positioned between the second composite layer (C2) and the recordable template layer (D),

(E2) optionally and preferably a protective film.

The films (E1) and (E2) are protective films or cover films that simultaneously can provide carrier function. The films (E1) and (E2) may be made of plastic or paper or composite materials. They shall be impermeable to actinic radiation.

Such a semi-finished product can be produced as follows:

(i) Providing a protective or carrier film (E1),

(ii) Applying and drying a formulation for a recordable template layer (D) on one side,

(iii) Applying and drying a formulation for a barrier layer (C1) onto layer (D),

(iv) Applying and drying a formulation for an adhesion modulating layer (C2) onto the barrier layer (C1),

(v) optionally applying a protective layer (E2) onto the adhesion modulating layer (C2).

The drying is performed at a temperature that depends on the solvents used, the thermal stability of the layer forming components and the desired drying time. Suitable drying temperatures are in the range of 50 to 150° C. All drying times preferably are of the same length and in the range of less than 5 min, such as 1 to 3 minutes, in particular about 2 minutes.

Together with a flexographic printing element comprising a carrier film (A), a relief forming polymer layer (B), optionally an adhesive layer between the relief forming polymer layer (B) and the carrier film (A) and optionally a peelable protective film or cover film (E3) on the relief forming polymer layer (B), such semi-finished product can be processed to a recording element as follows:

(i) removing optionally present protective films or cover films (E2), (E3) from the actinic radiation-transparent intermediate layer composite (C) and from the relief forming polymer layer (B)

(ii)transferring and laminating the semi-finished product made of film (E1) the recordable template layer (D) and the actinic radiation transparent intermediate layer composite (C) with the intermediate layer composite to the relief forming polymer layer (B) of the flexographic printing element—in other words—transferring and laminating the actinic radiation transparent intermediate layer composite (C) together with the recordable template layer (D) and the cover film (E1) onto the relief forming polymer layer (B) of the flexographic printing element.

Also an object of the present invention is a method for the production of high-resolution flexographic printing plates using a recording element of the invention and its imaging by means of digital information transmission using actinic laser radiation. This method comprises the following method steps:

(1) optionally, removing the cover film (E1)

(2) exposing the recordable template layer (D) to actinic laser radiation to form an exposed template layer,

(3) developing the exposed template layer (D) to form an imaged template layer (D),

(4) exposing the recording element provided with the imaged template layer (D) with actinic radiation through the imaged template layer (D),

(5) mechanically removing the template layer (D) and the intermediate layer composite (C), as well as chemically and/or thermally removing the not-polymerized portions of the relief-forming polymer layer (B) thus forming the flexographic printing plate,

(6) drying the obtained flexographic printing plate and

(7) optionally and preferably after-treating of the flexographic printing plate with UV light.

The removing of the intermediate layer composite (C) together with the imaged template layer (D) is preferably performed mechanically. The removing of the not-polymerized portions of the relief forming polymer layer (B) is preferably performed chemically. The removing of the intermediate layer composite as well as the removing of the not-polymerized portions of the relief forming polymer layer (B) can be performed at enhanced temperature.

### BRIEF DESCRIPTION OF THE DRAWINGS

Other embodiments, advantages and applications of the invention will become apparent from the dependent claims and from the Figures, wherein

FIG. 1 describes the production of a recording element starting from a semi-finished product with an intermediate layer composite (C) made of two composite layers (C1) and (C2) and

FIG. 2 describes the production of a flexographic printing plate starting from a recording element of FIG. 1.

### WAYS TO CARRY OUT THE INVENTION

The inventive recording element suitable for the production of high-resolution flexographic printing plates by means of digital information transfer that is imageable or imaged with actinic laser radiation contains or consists of the following layers, which are arranged on top of each other in the named order:

(A) a carrier film which may optionally be provided with an adhesive layer on the side provided with a photopolymerizable layer/relief forming polymer layer,

(B) a photopolymerizable layer/relief forming polymer layer which is soluble in organic solvents and/or aqueous solvents and/or becomes liquid or evaporates upon heating and which is crosslinkable by actinic radiation,

(C) an actinic radiation transparent intermediate layer composite as a separating element, wherein the intermediate layer composite consists of at least two and preferably two polymer layers lying on top of each other, wherein a second composite layer (C2) is an adhesion modulating layer arranged on the relief forming polymer layer and a first composite layer (C1) is a barrier layer for the diazonium compounds comprised in the recordable template layer (D) and arranged between the second composite layer (C2) and the recordable template layer (D),

(D) a recordable template layer comprising a monomeric diazonium compound which is photosensitive to actinic laser radiation and which undergoes a change in actinic density by development, or an imaged template layer wherein the monomeric diazonium compound is destroyed by actinic laser radiation in at least one area and has an increased actinic density in at least one unexposed area as a result of development. As protection against pollution, on the recordable template layer (D), the recording element optionally and preferably additionally comprises,

(E1) a peelable protective film or cover film.

The purpose of the recordable layer (D) is its imaging by means of laser radiation and subsequent development process to form a template (mask) for the actinic irradiation of the layer (B) with the desired high resolution. The resolution of the template layer (D) is in the molecular range.

(E1) is a peelable lightproof (actinic radiation-tight) protective film or cover film. The recording element preferably comprises such a protective film or cover film for protecting the recordable template layer (D) against pollution and light.

The recordable template layer (D) usually has a layer thickness of 1 μm to 50 μm, preferably from 3 μm to 30 μm, and can be imaged with actinic laser radiation of a power of preferably 10 to 1500 mJ/cm² in the spectral range of 330 nm to 430 nm, in particular from 50 to 1000 mJ/cm² in the specified spectral range.

Preference is given to a recordable template layer (D) which can be developed by means of alkaline solution or alkaline vapors, such as by means of ammonia, in particular ammonia vapor. As a result of the development the unexposed areas become less permeable to the actinic radiation suitable for cross-linking the relief forming polymer layer. Well suited are materials whose unexposed areas have a difference in the actinic density of >3.0 after development.

Preferred recordable template layers consist of at least 70% by weight, preferably at least 85% by weight of a mixture from

(i) at least one binder based on cellulose ester, in particular cellulose acetate propionate (CAP) and/or cellulose acetate butyrate (CAB), and

(ii) at least one diazonium compound of formula (I)

R—N⁺≡NX⁻ (I)

wherein R is a substituted or unsubstituted organic group such as an alkyl group, acyl group or aromatic group,

X⁻ is an anion, in particular selected from the group comprising BF₄⁻, AsF₆⁻, ClO₄⁻, SbF₆⁻, CF₃SO₃⁻, SO₄⁻, PF₆⁻ PO₄³⁻, NO₃⁻, Br⁻, Cl⁻, I⁻, F⁻, arylsulfonate, such as p-chlorobenzenesulfonate, alkylsulfonate, allylsulfonate, or a metal complex anion, e.g. ZnCl₃⁻, SnCl₆²⁻,

(iii) in combination with at least one reactive coupler compound.

The ratio of binder to diazo compound usually is from 50:1 to 1:2, preferably from 20:1 to 1:1, and the ratio of diazo compound to coupler compound from 4:1 to 1:4, preferably from 2:1 to 1:2.

Preferably, R is an aromatic group whose ring is substituted with the substituents A, B and C according to formula (Ia) independent of their position to the diazonium group.

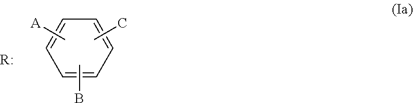

wherein

A, B and C may be the same or different and are selected from the group comprising halogen atom, hydrogen atom, amino groups, thio groups, nitro group, sulfo group, acyl group, carbalkoxy group, sulfonyl group, cyano group or carboxyl group.

In particular, the groups A, B and C have the following meaning in their preferred ortho, para or meta position to the diazonium group:

A in ortho position to the diazonium group is selected from the group comprising halogen atom, hydrogen atom, nitro group, sulfo group or organic group, the organic group being in particular an acyl group, carbalkoxy group, sulfonyl group, cyano group or carboxyl group,

B in para position to the diazonium group is selected from

(i) optionally monosubstituted or disubstituted amino groups, wherein the substituents are each independently selected from the group comprising alkyl groups, aryl groups, alkoxy groups and phenoxy groups, or the two substituents together with the nitrogen to which they are attached form a heterocycle, or

(ii) substituted thio groups wherein the substituent is selected from the group comprising alkyl groups and aryl groups.

C in meta position or in ortho position to the diazonium group is selected from the group comprising acyl groups, carbalkoxy groups, sulfonyl groups, nitro groups, cyano groups, carboxyl groups, sulfo groups, hydrogen or halogen.

An example of a suitable diazo salt is the diazonium compound {Ia) used in the examples with A: Cl, B: N(Et)₂, or N(Me)₂, C: H, X⁻:BF₄⁻ or PF₆⁻.

Unless otherwise stated, all alkyl groups and aryl groups may be substituted or unsubstituted, and the groups listed below, in the context of this invention, have the meaning:

“Acyl groups” are in particular aliphatic acyl groups with preferably up to about 6 carbon atoms in the alkyl group, for example formyl, acetyl, propionyl, butyryl, β-phenylacetyl and γ-chloropropionyl groups or aromatic acyl groups, such as the benzoyl group;

“Carbalkoxy groups” are in particular alkoxycarbonyl groups having preferably 1 to 8 carbon atoms in the alkoxy group;

“Sulfonyl groups” are, in particular, alkylsulfonyl groups, arylsulfonyl groups and aminosulfonyl groups;

“Sulfo groups” are in particular alkylsulfo groups and arylsulfo groups.

For the purposes of the present invention, “alkyl groups” are preferably linear or branched-chain, substituted or unsubstituted alkyl groups with from 1 to about 15 carbon atoms in the alkyl group, such as methyl, ethyl. Suitable substituents are, in particular, halogen atoms, such as chlorine atoms, hydroxyl groups, alkoxy groups with 1 to 5 carbon atoms, such as a methoxy group, phenoxy groups and/or benzylthio groups.

In the context of the present invention, “aryl groups” are preferably to be understood as meaning substituted and unsubstituted monocyclic and polycyclic aromatic groups with 6 to 10 carbon atoms, in particular the phenyl and naphthyl group. Suitable substituents are hydroxy, in particular alkyl groups with 1 to 5 carbon atoms, alkoxy groups with 1 to 5 carbon atoms and halogen atoms.

In the context of this invention suitable groups for R in formula (I) are e.g. as described in DE OS 2 202 251 on pages 3 to 8, and in DE 42 41 717 AI on p. 3, l. 30 to 46 and p. 4, l. 1 to p. 5, l. 50.

The at least one reactive coupler compound is in particular a coupler compound of the formula (II) or (III)

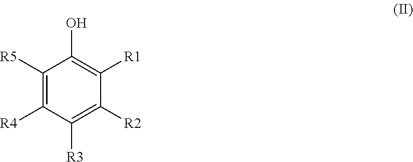

wherein R1, R2, R3, R4 and R5 may be the same or different and are selected from the group comprising —OH, —SO₃H, —CONH—R6 (R6=alkyl, aryl, cycloalkyl, alkoxy), alkoxy group, carboxy group, guanidine group, amino group, acylamido group, thiourea group, thio group, hydrogen or halogen, or

R1 and R2 or R2 and R3 together form a butadienyl group such that together with the phenol ring they form a substituted or unsubstituted aromatic bicycle (naphthol structure) according to formula (IIa) or (IIb)

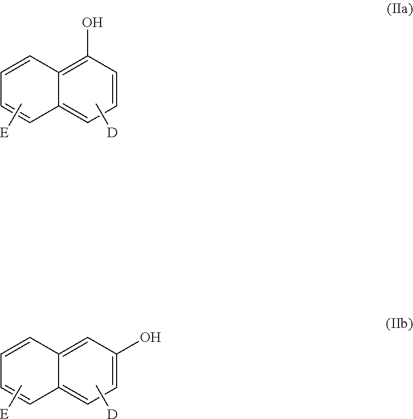

wherein D und E may be the same or different and are selected from the group comprising —OH, —SO₃H, —CONH—R6 (R6=alkyl, aryl, cycloalkyl, alkoxy), alkoxy group, carboxy group, guanidine group, amino group, acylamido group, thiourea group, thio group, hydrogen or halogen,

or

R1 or R2 or R3 are —OH such that an unsubstituted and substituted dihydroxybenzene of formula (IIc), (IId) or (IIe) is present

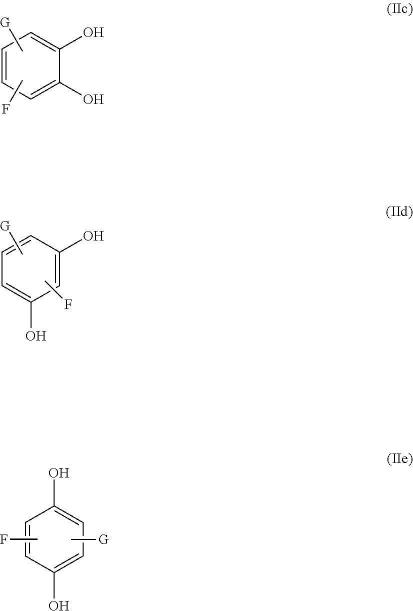

or

R1=R5=—OH or R1=R3=—OH or R2=R4=—OH, such that an unsubstituted or substituted trihydroxybenzene of formula (IIf), (IIg) or (IIh) is present

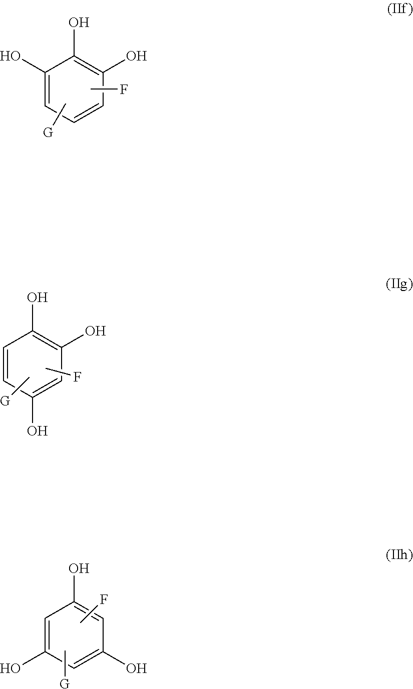

wherein F and G may be the same or different and are selected from the group comprising —OH, —SO₃H, —CONH—R6 (R6=alkyl, aryl, cycloalkyl, alkoxy), alkoxy group, carboxy group, guanidine group, amino group, acylamido group, thiourea group, thio group, hydrogen or halogen, e.g.

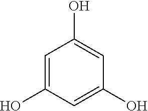

or wherein the coupler compound is a biphenol or bisphenol of formula (III)

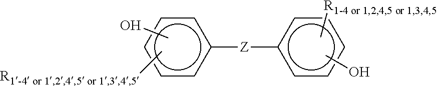

wherein Z=bond, —O— or —S—, and

wherein R1, R2, R3, R4, R5 and R1′, R2′, R3′, R4′, R5′ may be the same or different and are selected from the group comprising —OH, —SO₃H, —CONH—R6 (R6=alkyl, aryl, cycloalkyl, alkoxy), alkoxy group, carboxy group, guanidine group, amino group, acylamido group, thiourea group, thio group, hydrogen or halogen, e.g.

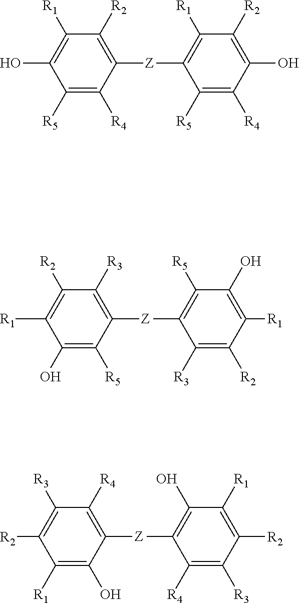

or a corresponding biphenol or bisphenol analogous to the formula (III), with at least 2 OH substituents per each phenyl ring, wherein the remaining R have the above indicated meaning, e.g

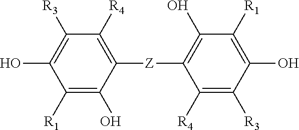

Suitable coupler compounds are e.g. the 3,5-dihydroxybenzoic acid (coupler compound (IId) with F=H and G=(HO)C=0)) and the 2,2′-biphenol (coupler compound (III) with R1 to R4=H, R1′ to R4′=H and Z=bond) used in the examples.

In addition to the above-mentioned binders, diazonium compounds and reaction couplers, it is possible to add acids to stabilize the template layer (D), e.g. organic acids, such as citric acid, oxalic acid, sulfosalicylic acid, ascorbic acid, sulfonic acid, whose pKa is between −4.0 and 5.0 and that are suitable for adjusting a pH of the final coating solution of below 5.0 (in particular pH below 3.0). In order to improve the flow properties wetting agents can be added, in order to increase the flexibility of the layer plasticizers can be added, in order to adjust the roughness of the layer surface matting agents, in particular based on silicate, aluminate or polymer, such as polymethyl methacrylate (PMMA), can be added and in order to adjust the adhesion properties of the layer crosslinking agents, in particular melamine resin, can be added.

The recording element of the present invention comprises an intermediate layer composite (C) that is transparent to actinic radiation. Such an intermediate layer composite that is transparent to actinic radiation has two main functions:

a) On the one hand the clean separation of the relief forming polymer layer (B) from the recordable template layer (D), i.e. the prevention of diffusion between the layers. The diffusion of monomers and additives comprised in the relief forming polymer layer (B) affect the stability of the recordable template layer (D) and its resolution.

b) On the other hand the easy removal of the imaged template layer (D) with the intermediate layer composite (C) from the relief forming polymer layer (B) after exposure of the recording element with actinic radiation through the imaged template layer. It has namely been found that a pure intermediate layer of e.g. polyester of copolyester prevents diffusion but cannot be peeled off the relief forming polymer layer (B).

Usually the actinic radiation transparent intermediate layer composite (C) has a thickness of up to 100 μm, such as 0.1 μm to 100 μm, preferably from 0.2 μm to 50 μm, in particular of 0.4 μm to 30 μm, more preferably from 0.6 μm to 20 μm, such as 8 μm.

The actinic radiation transparent intermediate layer composite (C) consists of at least 2 polymer comprising layers lying on top of each other: The first compound layer (C1) is a blocking layer and serves as barrier layer. In general and preferably it is in direct contact with the recordable template layer (D). It does not only prevent the migration and/or diffusion of each of the components comprised in the template layer (D) but also subsequent diffusion of oxygen into the second composite layer (C2) that is arranged on the relief forming polymer layer and into the relief forming polymer layer (B). Once the EXPOSURE process is finished, the second composite layer (C2) can be easily removed mechanically.

Preferred composite layers (C1) and (C2) of the intermediate layer composite (C) that is transparent to actinic radiation are preferably composed as follows:

The composite layer (C1) consists of at least 70% by weight, preferably at least 85% by weight of at least one binder, which is based on at least one water-soluble and/or organic solvent-soluble polymer or copolymer. The oxygen permeability of the composite layer is less than 1000 (cm³×100 μm)/(m²×d×bar) and preferably is less than 500 (cm³×100 μm)/(m²×d×bar). Such a composite layer (C1) has a thickness of up to 50 μm, like from 0.05 μm to 50 μm, preferably from 0.1 μm to 25 μm, in particular from 0.2 μm to 15 μm, especially preferred from 0.3 μm to 10 μm.

Examples of suitable polymers for the composite layer (C1) comprise polymers or copolymers that can be dissolved in suitable solvents and solvent compositions, such as naphtha, aromatic compounds, dioxane, alcohols, ketones, esters or mixtures thereof. Such polymers or classes of polymers are e.g.

Polyesters, like polyethylene terephthalate (PET), polybutylene terephthalate (PBT), polyethylene naphthalate (PEN),

polymethacrylate, like polymethylmethacrylate (PMMA),

polylactic acid (PLA),

polycarbonate,

polyamide (PA),

non-halogenated or halogenated polyolefins, like polyethylene (PE), polypropylene (PP), polymethylpentene (PMP) and polybutylene (PB, PIB) or fluoropolymers, like polytetrafluoroethylene (PTFE), polyvinylidene chloride (PVDC), polyvinylidene fluoride (PVDF), ethylene tetrafluoroethylene (ETFE), polyvinyl fluoride (PVF), perfluoroethylenepropylene (PEP, FEP),

polyarylsufones, like polysulfone (PSU) and polyethersulfone (PES),

polymers of vinyl alcohols, like polyvinylalcohol, polyvinylacetate (PVA, PVAC), ethylene vinylacetate copolymer (EVAC), ethylene vinylalcohol copolymer (EVOH) and

mixtures thereof.

Preferably suited are all saturated and unsaturated CO-polyesters, like polyethylene terephthalate (PET), polybutylene terephthalate (PBT), polyethylene naphthalate (PEN) and polymethylmethacrylate (PMMA), polylactic acid (PLA), and mixtures thereof, in particular with a molecular weight over 1000, and polymers obtainable under trademarks like Dynapol© and Vitel©.

In order to improve the flowability, wetting agents can be added, in order to enhance the flexibility of the layer, plasticizers can be added, in order to optimize the adhesion of the barrier layer (C1) to the template layer (D) and to the adhesion modulating layer (C2), intermediate layer adhesion additives can be added, in order to improve the cohesion features, cohesion additives, like nano particles of silicon oxide (SiO2, SiOx) or aluminum oxide (AlO₂H, Al(OH)₃, Al₂O₃) or cross-linking agents, like melamine resins can be added.

The composite layer (C2) consists of at least 70% by weight, preferably at least 85% by weight of at least one binder, which is based on at least one water-soluble and/or organic solvent-soluble polymer or copolymer, has a peeling force to the relief forming polymer layer (B) of between 0.1 N/m and 100 N/m and an elongation between 50-1500%. Such a composite layer (C2) has a thickness of up to 50 μm, like from 0.05 μm to 50 μm, preferably from 0.1 μm to 25 μm, in particular from 0.2 μm to 15 μm, especially preferred from 0.3 μm to 10 μm.

Examples of suitable polymers for composite layer (C2) comprise soft-elastic and/or thermoplastic polymers or copolymers from the classes

polyvinyl alcohols,

partially or highly hydrolyzed (highly saponified) polyvinyl carboxylates,

polyvinyl acetates,

poly (ethylene oxide-vinyl alcohol) copolymers,

polyvinyl butyral,

polyamide,

polyurethane,

polyvinylpyrrolidone,

(silicone-polyurethane) copolymers,

polyethylene vinylacetate,

polyolefins,

polystyrene homopolymers and co-polymers,

gelatine

and mixtures thereof.

Polymers and copolymers from the group consisting of polyvinyl alcohol, polyvinyl pyrrolidone, polyamide, polyurethane, (silicone-polyurethane) copolymers, gelatine and mixtures thereof are preferably suitable. Also suitable are polymers obtainable under trademarks like Technomelt© or Thermelt©.

Wetting agents may be added to improve flow properties and to increase flexibility of the layer, plasticizers may be added.

The relief forming polymer layer (B) of the recording element usually has a layer thickness of 200 μm to 8000 μm, in particular 300 μm to 6000 μm. It contains or consists of a mixture of at least one elastomeric binder, at least two ethylenically unsaturated copolymerizable organic compounds (monomers for the formation of, for example, poly (styrene/isoprene/styrene) block copolymers) and at least one photoinitiator or a photoinitiator system, as well as, where appropriate, further additives, such as plasticizers.

Commercially available flexographic printing elements of the type (A)+(B)+(E3), which, after removal of the cover film (E3), can be used as part of the recording material of the invention, are available from manufacturers such as Dupont, Flint, Kodak and Fuji under the designation:

Dupont: Cyrel NOW

Flint: Nyloflex ACE 170

Kodak: FLEXCEL NXH plate or Flexcel SR plate

Fuji: Flenex FW

The carrier film (A) of the inventive recording element usually has a thickness of 50 μm to 300 μm.

Suitable carrier films (A) are preferably made of plastic, in particular of UV-transparent plastic, such as PET, PBT, PEN, or polycarbonate. Particularly suitable are PET films having a thickness of 50 to 300 μm, preferably 100 to 200 μm. Optionally, the carrier films (A) may be treated with conventional adhesion-promoting layers.

A further aspect of the invention relates to a semi-finished product for producing a recording element of the invention or for the production of a flexographic printing plate. Such a semi-finished product is characterized by the fact that it contains or consists of

(E1) a peelable protective film or cover film that is light impermeable and that also serves as carrier,

(D) a recordable template layer comprising a monomeric diazonium compound which is photosensitive to actinic laser radiation and undergoes a change in actinic density by development,

(C) an actinic radiation transparent intermediate layer composite consisting of at least two layers lying on top of each other, wherein a first composite layer C1) is a barrier layer against the diazonium compounds comprised in the recordable template layer (D) and arranged on the recordable template layer (D), and wherein on this first composite layer (C1) a second composite layer (C2) is arranged that is an adhesion modulating layer that modulates the adhesion of the relief forming polymer layer upon further processing to the recording element.

In one embodiment, the semi-finished product comprises a peelable protective film or cover film (E2) on the actinic radiation transparent intermediate layer composite (C)

A further aspect of the present invention is a method for producing a recording element of the invention using a semi-finished product of the invention and a flexographic printing element comprising a carrier film (A), a relief forming polymer layer (B), optionally an adhesive layer between the relief forming polymer layer (B) and the carrier film (A) and optionally a peelable protective film or cover film (E3) on the relief forming polymer layer (B).

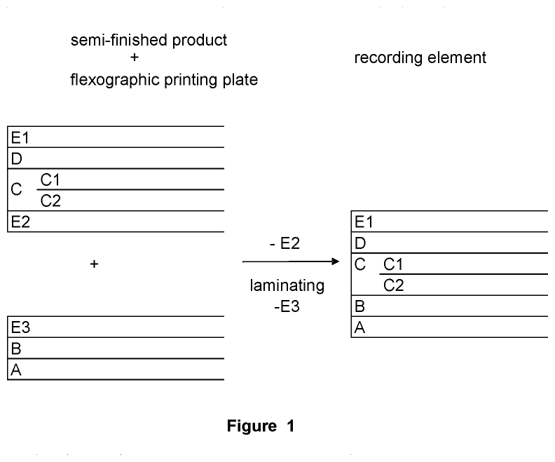

The method comprises the following steps that are also shown in FIG. 1:

(i) removing any optionally present protective films or cover films (E2), (E3) from the actinic radiation transparent intermediate layer compound (C) and from the relief forming polymer layer (B) of the flexographic printing element,

(ii) transferring and laminating the actinic radiation transparent intermediate layer composite (C) together with the recordable template layer (D) and the cover film (E1) onto the relief forming polymer layer (B) of the flexographic printing element.

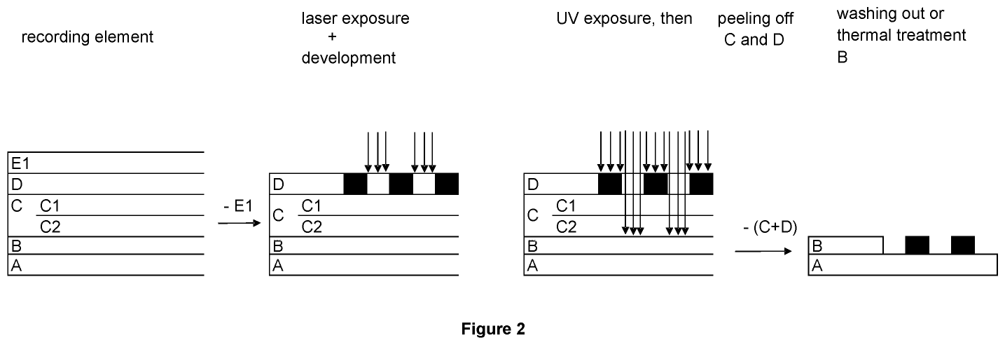

A further aspect of the present invention relates to a method for producing high-resolution flexographic printing plates using a recording element of the invention and imaging by means of digital information transmission using actinic laser radiation. This method that is also shown in FIG. 2 comprises the following method steps:

(1) peeling off the cover film (E1),

(2) exposing the recordable template layer (D) by means of actinic laser radiation to form an exposed template layer,

(3) developing the exposed template layer (D) to form an imaged template layer (D),

(4) exposing the recording element provided with the imaged template layer (D) to actinic radiation through the imaged template layer (D),

(5) removing the template layer (D), and the present intermediate layer composite (C) as well as the not polymerized portions of the relief-forming layer (B) with forming the relief of the flexographic printing plate,

(6) drying the resulting flexographic printing plate and

(7) optionally and preferably after-treating of the flexographic printing plate with UV light.

In the methods for the production of flexographic printing plates, the template layer (D) that is recordable by means of actinic radiation, usually is exposed to actinic laser radiation of 10 to 1500 mJ/cm² in the spectral range of 330 nm to 430 nm, in particular 50 to 1000 mJ/cm² in the specified spectral range, and after exposure developed by means of alkaline solution or alkaline vapor, such as ammonia, in particular by means of ammonia vapor.

For exposure of the relief forming polymer layer (B) through the imaged template layer (D) and the actinic radiation transparent layer composite (C) actinic UV radiation of >5 to 100 J/cm² in a spectral range from 200 nm to 450 nm is suitable.

After exposure of the relief forming polymer layer to a radiation energy and for a time resulting in the crosslinking of the exposed areas

the intermediate layer composite (C) can be mechanically peeled off together with the imaged template layer (D), and the not polymerized parts of the relief forming polymer layer (B) can be removed
by means of a leaching agent containing or consisting of water and/or solvent or
by means of a thermic method that achieves melting and/or evaporating through warming or heating.

### EXAMPLES

Preparation of Recording Elements of the Invention

The preparation of the inventive recording elements can be carried out in 3 stages:

1.—Production of a flexographic printing element: The components of the photopolymerizable relief forming polymer layer (B) are applied to a carrier film (A) by means of an extruder. When manufacturing a flexographic printing element, a protective film/cover film (E3) can be laminated to the outside of the relief forming polymer layer (B). Such a flexographic printing element with or without the protective film/cover film (E3) was used as the starting material for the following examples. Suitable flexographic printing elements are commercially available. In the following examples the flexographic plate Nyloflex ACE 170 from the company Flint was used.

2.—A PET film (E1) with or without an adhesive layer was coated with the recordable template layer (D). On top of this layer the intermediate layer composite (C) was applied as follows: The template layer (D) on the PET-film (E1) was first coated with the first composite layer (C1), the barrier layer/blocking layer and then the adhesion modulating layer (C2) was applied on top of the barrier layer. Optionally, a cover layer (E2) on the adhesion modulating layer serves as protective film of the semi-finished product.

3.—After removing the protective films (E2) and (E3) the composite of carrier film, protective film or cover film (E1) the recordable template layer (D) and the intermediate layer composite (C) was laminated onto the flexographic printing element (layer (C) to layer (B)).

Preparation of the Coating Solution of the Imageable Template Layer (D):

56 g of methyl ethyl ketone and 30 g of methanol were placed in a glass container. Then, 9 g of cellulose acetate propionate (CAP) binder (available from the firm Sigma-Aldrich) were stirred in at room temperature. After 40 minutes, 0.9 g of benzenesulfonic acid (available from the firm Sigma-Aldrich) were stirred in. After 20 minutes, 2.0 g of diazonium compound (Ia))[A: Cl, B: N(Et)₂, or N(Me)₂; C: H, X⁻:BF₄⁻ or PF₆⁻] (available from the firm Chemos GmbH) were stirred in. 20 Minutes later, 2 coupler compounds (II) were added successively: 0.28 g of 3,5-dihydroxybenzoic acid (coupler compound (IId) with F=H and G=(HO)C=0)) and 1.70 g of 2,2′-biphenol (coupler compound (III) with R1 to R4=H, R1′ to R4′=H and Z=bond) (obtainable from the firm Aldrich Chemical)) and 0.20 g of a silicone-containing surface additive (BYK-300; obtainable from the firm BYK).

Preparation of the Coating Solution of the Intermediate Layer Composite (C):

Barrier Layer (C1)

Linear Copolyesters/Dynapol©

In a glass container, 65 g of toluene were mixed with 15 g 1,4-dioxane. Thereafter, 20 g of copolyester Dynapol© L 210 (available from the firm Evonic) were added and stirred for 3 hours. The finished solution was ready for use.

Dynapol L 210 is described in the technical data sheet of “Universal Selector” by SpecialChem dated 17 Apr. 2017 as saturated, linear, copolyester with high molecular weight.

Linear Copolyesters/Vitel©

In a glass container, 75 g of toluene were mixed with 10 g 1,4-dioxane. Thereafter, 15 g of copolyester Vitel© 2475 (available from the firm Bostik) were added and stirred for 3 hours. The finished solution was ready for use.

Vitel© 2475 is described in the technical data sheet dated 14 Feb. 2019 “Bostik Smart adhesives” VITEL© 2475 Experimental Copolyester coating resin as saturated, linear, copolyester resin with high molecular weight.

Adhesion Modulating Layer (C2)

Polyvinyl Butyral (Mowital B 16 H) as Adhesion Modulator

In a glass container, 70 g of iso-propanol were mixed with 20 g of water. Thereafter, 10 g of Mowital B 16 H (available from the firm Kuraray) were added and stirred for 60 minutes. The finished solution was ready for use.

According to the technical data sheet “Mowital” of Kuraray of August 2016, Mowital B 16 H has a glass transition temperature of 63° C.

Polyvinyl Alcohol as Adhesion Modulator:

In a glass container, 95 g of water were mixed with 0.05 g of Capstone FS-30 (ethoxylated, nonionic fluoride surfactant). Thereafter, 5 g of polyvinyl alcohol Poval 40-88 partially saponified (available from the firm Kuraray) were added and stirred for 60 minutes. The finished solution was ready for use.

Polyamide as Adhesion Promotor

In a glass container, 42 g of iso-propanol were mixed with 42 g of toluene. Thereafter, 16 g of polyamide Technomelt PA 6900 E (available from the firm Henkel) were added and stirred for 60 minutes. The finished solution was ready for use.

In the technical data sheet of January 2013, Technomelt PA 6900 is described as consisting of one part and being based on polyamide technology.

Flexographic Printing Element

As a flexographic printing element for the various examples, the plate “Nyloflex© ACE 170” from the firm Flint without the recordable layer was used. It consists of a carrier film (A) with about 125 μm thickness and a photopolymerizable relief forming polymer layer (B) with about 1650-1700 μm thickness and a protective film (E3) with about 125 μm thickness.

### Comparative Example I

A diazofilm DPC-HRP from the firm Folex AG was used as the recordable layer. The imaged template layer was obtained according to process steps a) and b) of comparative example V and then copied onto the flexographic printing element Nyloflex® ACE 170 (without carbon black containing layer (LAMS)) according to the method step c) of comparative example V.

### Comparative Example II

The recordable layer (D) was a carbon black containing layer (LAMS), which is part of the Nyloflex® ACE 170 digital from Flint. The carbon black containing layer was imaged with a laser apparatus of type Multi DX 220 from the firm Lüscher. Thereafter, the imaged recording element was exposed and further processed according to method step c) of comparative example V.

### Comparative Example III

The recordable layer was a carbon black containing layer (LAMS), which is part of Dupont's CYREL® DSP plate. The carbon black containing layer was exposed to Multi DX 220 from the firm Lüscher. Thereafter, the imaged recording element was exposed and further processed according to method step c) of comparative example V.

### Comparative Example IV

The recordable layer was a carbon black containing layer (LAMS), which is part of the digital LUX-ITP plate of Mac Dermid. The carbon black containing layer was exposed with a laser apparatus of type Multi DX 220 from the firm Lüscher. Thereafter, the imaged recording was exposed and further processed element according to method step c) of comparative example V.

### Comparative Example V: (According to EP 3 401 732 A1)

The recordable template layer (D) was applied to a thin film (E1) as carrier film and then laminated to the relief forming polymer layer (B) of the flexographic printing element. (according to comparison of invention EP 3401 732 A1)

The formulation of the recordable template layer (D) was applied to a 6 μm PET film (E1) with an applied amount of approximately 15 g/m² solid and then dried in an oven at a temperature of 130° C. for 2 min. In comparison to the intermediate layer composite of the present invention, the intermediate film (C) with the layer (D) was stored at room temperature, about 20° C. and 50% relative moisture, for at least 24 hours. Due to the production and further processing within the same laboratory premises, covering the recordable template layer (D) with a cover film (E2) was waived. Following storage, the intermediate film (C) with the layer (D)—after removal of the protective film (E3)—was laminated onto the relief forming polymer layer (B) of the flexographic printing element. A recording element according to EP 3 401 732 A1 was obtained which is ready for the production of the finished flexographic printing plate.

a) The recording element obtained was exposed to a laser illuminator of the type Multi DX 220 from the firm Lüscher with an energy of 500 mJ/cm² at a wavelength of 405 nm and with 2540 dpi and

b) subsequently developed in ammonia vapor (generated from an alkaline solution (25% ammonia) at a temperature of at least 70° C., maximum 95° C.).

c) Thereafter, the printing plate with the template obtained in step b), or the imaged template layer (D), respectively, was exposed to UV-A radiation by means of a UV exposer of the type Cyrel 2001 E for 50 sec. (base)/600 sec. (front).

d) Subsequently—after peeling off the film (C) together with the layer (D)—the not polymerized areas of the relief forming polymer layer (B) were leached for 15 min with Nylosolv® A from the firm Flint in a Dupont processor of type CYREL 3000P.

e) The resulting flexographic printing plate was dried for 120 minutes at a temperature of approx. 65° C.

f) Thereafter, the flexographic printing plate was post-exposed:

First about 11 Minutes with UV-C radiation to minimize stickiness at the surface,

then approx. 10 Minutes with UV-A radiation to achieve a sufficient post-curing.

The flexographic printing plate produced in this way was ready for use.

### Comparative Example VI: (According to EP 3 401 732 A1)

As comparative example V but the recordable template layer (D) was applied onto a thin PET-film (E1), the thickness of which was 12 μm, and then laminated onto the relief forming polymer layer (B) of the flexographic printing element.

The obtained recording element for the production of the finished flexographic printing plate was provided as described in comparative example V and the production of the final flexographic printing plate was performed by further treatment in analogy to comparative example V, steps a) to f).

### Example 1

According to the invention, the recordable template layer was applied to a flexographic printing element with an intermediate layer composite (C) made of a blocking layer (C1) and an adhesion modulating layer (C2)

The formulation of the recordable template layer (D) was applied to a 100 μm PET film (E1) without an adhesive layer in an applied amount of about 15 g/m² solid substance and then dried in an oven at a temperature of 130° C. for 2 min. Subsequently, in a second step, the barrier layer (C1) was applied to layer (D) in an applied amount of about 6 g/m² and dried in the oven at a temperature of 80° C. for 2 minutes. As binder of the barrier layer (C1) Dynapol® L210 was used.

Subsequently, in a third step, the adhesion modulating layer (C2) was applied to the layer (C1) in an applied amount of about 6 g/m² and dried in the oven at a temperature of 80° C. for 2 min. As binder of the adhesion modulating layer (C2) Technomelt PA 6900 E was used.

The thus prepared three-layered material made of the recordable template layer (D) and the actinic laser radiation transparent intermediate layer composite (C) was transferred to the relief forming polymer layer (B) of the flexographic printing element with simultaneous removal of carrier film (E1). An inventive recording element was obtained that is ready for the production of the finished flexographic printing plate.

The production of the flexographic printing plate was performed as described in comparative example V with the exception that instead of film (C) in step d) the intermediate layer composite (C) was peeled off.

The such prepared flexographic printing plate was ready for use.

### Example 2

According to the invention, the recordable template layer was applied together with an intermediate layer compound (C) made of a blocking layer (C1) and an adhesion modulating layer (C2).

The procedure was analogous to Example 1, with the difference that as a binder for the adhesion modulating layer (C2) polyvinyl alcohol was used instead of Technomelt PA 6900 E.

### Example 3

According to the invention, the recordable template layer was applied together with the intermediate layer composite (C) made of a blocking layer (C1) and an adhesion modulating layer (C2).

The procedure was analogous to example 1 with the difference that as the binder of the adhesion modulating layer (C2) Mowital® B 16 H was used instead of Technomelt PA 6900 E.

### Example 4

According to the invention, the recordable template layer was applied together with the intermediate layer composite (C) made of a blocking layer (C1) and an adhesion modulating layer (C2).

The procedure was analogous to example 1 with the difference that the applied amount of blocking layer (C1) and adhesion modulating layer (C2) was reduced from 6.0 g/m2 each to 3.5 g/m2 each.

### Example 5

According to the invention, the recordable template layer was applied together with the intermediate layer composite (C) made of a blocking layer (C1) and an adhesion modulating layer (C2).

The procedure was analogous to example 1 with the difference that as the binder of the blocking layer (C1) Vitel® 2475 was used instead of Dynapol® L210.

### Comparison of Comparative Examples I to VI and IV with Examples 1 to 5 According to the Invention

Evaluation

The resulting flexographic printing plates were examined under the microscope at a 30-fold magnification using the imaged UGRA/FOGRA digital plate wedge, the differently imaged font sizes (0.5 pt to 8 pt) as well as the imaged dot sizes and line sharpness (from 20 to 600 μm). The following features were evaluated:

1. Determination of spot size in μm: the imaged spots were measured and evaluated in the microscope and the smallest spot size that was visible and printable was recorded as reference value.

2. Determination of font size in pt: The imaged letters on a scale of 0.5 to 6.0 pt were evaluated under a microscope and the smallest font size, which was judged to be readable and sharp, was recorded as a reference value.

3. Determination of the line width μm: The imaged lines were measured and evaluated in the microscope. The narrowest visible and sufficiently sharp line for print reproduction was taken as the reference value.

4. Determination of the lowest and highest tonal value (%): On the gradient/step wedge (UGRA/FOGRA digital plate wedge), the graduated tonal values from 0 to 100% were measured and evaluated by microscope. The smallest and the highest tonal value of the gradient wedge/step wedge with sufficient profile for the print reproduction were taken as reference values.

5. Determination of the uniformity prior to processing: After production of the recording element in A4 size by laminating an inventive semi-finished product and a commercial printing plate and removing of the cover film E1 but before exposing the plate with a laser and developing, the number of defects and irregularities was counted.

6. Determination of the uniformity after processing: A recording element in A4 size produced in analogy to number 5 was exposed with a laser, developed and exposed with UV-light through the obtained mask. The layer (D) with the film or the layer composite was peeled off. The plate was washed out/leached. Then again the defects and irregularities, like imaging of the wrinkles, displacements of letters in comparison with a reference etc., of the ready to use plate were determined.

TABLE 1
Evaluation of the features - results

| | | | line | | Uniformity prior | Uniformity after |
|---|---|---|---|---|---|---|
| | dot size | font size | width | gradient wedge | to processing | processing |
| | visible | legible | visible | lowest/highest | Number of | Number of |
| | from: | from: | from: | tonal value | defects/ | defects/ |
| | [μm] | [pt] | [μm] | [%] | irregularities | irregularities |
| Example | 1 | 2 | 3 | 4 | 5 | 6 |
| Comp. I | 100 | 1 | 40 | 3.0/95.0 | 0 | 0 |
| Comp. II | 100 | 1 (frayed) | 50 | 3.0/97.0 | 0 | 0 |
| Comp. III | 500 | 2 (frayed) | 100 | 4.0/94.0 | 0 | 0 |
| Comp. IV | 75 | 1 | 50 | 1.0/97.0 | 0 | 0 |
| Comp. V | 40 | 0.5 | 20 | 1.0/97.0 | 22 | 33 |
| Comp. VI | 50 | 1 | 40 | 1.0/97.0 | 12 | 21 |
| 1 | 30 | 0.5 | 20 | 1.0/98.0 | 0 | 0 |
| 2 | 30 | 0.5 | 20 | 1.0/98.0 | 0 | 0 |
| 3 | 30 | 0.5 | 20 | 1.0/98.0 | 0 | 0 |
| 4 | 20 | 0.5 | 20 | 1.0/99.0 | 0 | 0 |
| 5 | 30 | 0.5 | 20 | 1.0/98.0 | 0 | 0 |

The experiments 1 to 5 according to Table 1 prove that the recording elements of the invention have a high resolution, can image very fine and faultless surface structures, can easily be processed during production and—in total—clearly exceed the state of the art.

While preferred embodiments of the invention have been described in the present application, it is to be understood that the invention is not limited to these and may be embodied otherwise in the scope of the appended claims.

1. A recording element which is suitable for the production of high-resolution flexographic printing plates by means of digital information transmission, that can be imaged with actinic laser radiation and that comprises or consists of the following layers arranged one above the other in the stated sequence:
(A) a carrier film, optionally provided with an adhesive layer on the side provided with a photopolymerizable layer/relief forming polymer layer,
(B) a photopolymerizable layer/relief forming polymer layer which is soluble in organic solvents and/or aqueous solvents and/or can be molten of is volatile upon heating and which is cross-linkable by actinic radiation,
(C) an actinic radiation transparent intermediate layer composite, comprising at least two polymer comprising composite layers lying on top of each other, wherein a second composite layer (C2) is an adhesion modulating layer lying on top of the relief forming polymer layer and a first composite layer (C1) is a barrier layer for the diazonium compounds comprised in the recordable template layer (D) and positioned between the second composite layer (C2) and the recordable template layer (D),
(D) a recordable template layer comprising a monomeric diazonium compound which is photosensitive to actinic laser radiation and undergoes a change in actinic density by development or an imaged template layer in which the monomeric diazonium compound is destroyed by actinic laser radiation in at least an area and has an increased actinic density in at least one unexposed area due to development.
(E1) optionally a peelable protective film or cover film.

2. The recording element of claim 1, wherein the actinic radiation transparent intermediate layer composite (C) has a thickness of up to 100 μm, such as 0.1 μm to 100 μm, wherein the second composite layer (C2) of the intermediate layer composite (C) has a thickness of up to 50 μm, such as 0.05 μm to 50 μm, and/or wherein the first composite layer (C1) of the intermediate layer composite (C) has a thickness of up to 50 μm, such as 0.05 μm to 50 μm.

3. The recording element of claim 1, wherein
the second composite layer (C2) of the intermediate layer composite (C) has a peeling force to the relief forming polymer layer (B) of 0.1 N/m to 200 N/m, and
an elongation of 50 to 1500.

4. The recording element of claim 1, wherein the first composite layer (C1) consists of at least 70% by weight of at least one binder which is based on at least one water-soluble and/or organic solvent-soluble polymer or copolymer and that has an oxygen permeability of less than 1000 (cm³×100 μm)/(m²×d×bar), and
the second composite layer (C2) consists of at least 70% by weight of at least one binder which is based on at least one water-soluble and/or organic solvent-soluble soft elastic and/or thermoplastic polymer or copolymer.

5. The recording element of claim 1, wherein the binder of the first composite layer (C1) is selected from the group consisting of
polyesters, like polyethylene terephthalate (PET), polybutylene terephthalate (PBT), polyethylene naphthalate (PEN),
polymethacrylate, like polymethylmethacrylate (PMMA),
polylactic acid (PLA),
polycarbonate,
polyamide (PA),
non-halogenated or halogenated polyolefins, like polyethylene (PE), polypropylene (PP), polymethylpentene (PMP) and polybutylene (PB, PIB) or fluoropolymers, like polytetrafluoroethylene (PTFE), polyvinylidene chloride (PVDC), polyvinylidene fluoride (PVDF), ethylene tetrafluoroethylene (ETFE), polyvinyl fluoride (PVF), perfluoroethylenepropylene (PEP, FEP),
polyarylsufones, like polysulfone (PSU) and polyethersulfone (PES),
polymers of vinyl alcohols, like polyvinylalcohol, polyvinylacetate (PVA, PVAC), ethylene vinylacetate copolymer (EVAC), ethylene vinylalcohol copolymer (EVOH) and
mixtures thereof, in particular saturated and unsaturated polyesters, like polyethylene terephthalate (PET), polybutylene terephthalate (PBT), polyethylene naphthalate (PEN), polymethylmethacrylate (PMMA), polylactic acid (PLA), and mixtures thereof, all with a molecular weight above 1000, and
wherein the binder of the second composite layer (C2) is selected from
polyvinyl alcohols,
partially or highly hydrolyzed (highly saponified) polyvinyl carboxylates,
polyvinyl acetates,
poly (ethylene oxide-vinyl alcohol) copolymers polyvinyl butyral,
polyamide,
polyurethane,
polyvinylpyrrolidone,
(silicone-polyurethane) copolymers,
polyethylene vinylacetate,
polyolefins,
polystyrene homopolymers and co-polymers,
gelatine
and mixtures thereof, in particular polyvinyl alcohol, polyvinyl pyrrolidone, polyamide, polyurethane, (silicone-polyurethane) copolymers, gelatine and mixtures thereof.

6. The recording element of claim 1, wherein the recordable template layer (D) has a layer thickness of 1 μm to 50 μm, and/or can be exposed with actinic laser radiation of a power of 10 to 1500 mJ/cm² in the spectral range from 330 nm to 430 nm.

7. The recording element of claim 1, wherein the recordable template layer can be developed by means of an alkaline solution or alkaline vapors, like ammonia vapor, such that the unexposed areas become less permeable to actinic radiation.

8. The recording element of claim 1, wherein the recordable template layer consists of at least 70% by weight of a mixture of at least one cellulose ester-based binder and a diazonium compound and a reactive coupler compound, wherein
the diazonium compound is a diazonium salt according to formula (I),
R—N≡N⁺X⁻ (I)
wherein R is a substituted or unsubstituted organic group such as an alkyl group, acyl group or aromatic group,
X⁻ is an anion, in particular selected from the group comprising BF₄⁻, AsF₆⁻, ClO₄⁻, SbF₆⁻, CF₃SO₃⁻, SO₄⁻, PF₆⁻PO₄³⁻, NO₃⁻, Br⁻, Cl⁻, I⁻, F⁻, arylsulfonate, such as p- chlorobenzenesulfonate, alkylsulfonate, allylsulfonate, or a metal complex anion, e.g. ZnCl₃⁻, SnCl₆²⁻,
and the reactive coupler compound is in particular a coupler compound of formula (II), 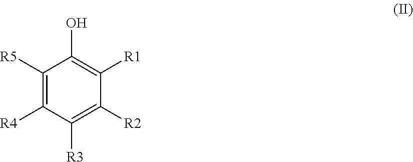
wherein R1, R2, R3, R4 and R5 may be the same or different and are selected from the group comprising —OH, —SO₃H, —CONH—R6 (R6=alkyl, aryl, cycloalkyl, alkoxy), alkoxy group, carboxy group, guanidine group, amino group, acylamido group, thiourea group, thio group, hydrogen or halogen, or
R1 and R2 or R2 and R3 together form a butadienyl group,
and wherein the ratio of binder to diazo compound usually is from 50:1 to 1:2, and the ratio of diazo compound to coupler compound is from 4:1 to 1:4.

9. The recording element of claim 1, wherein the relief forming polymer layer (B) has a layer thickness of 200 μm to 8000 μm, and/or comprises or consists of at least one elastomeric binder, at least two ethylenically unsaturated copolymerizable organic compounds (monomers) and at least one photoinitiator or a photoinitiator system.

10. A semi-finished product for producing a recording element of claim 1, containing or consisting of the following layers:
(E1) a peelable cover film or protective film that also serves as carrier,
(D) a recordable template layer comprising a monomeric diazonium compound which is photosensitive to actinic laser radiation and undergoes a change in actinic density by development,
(C) an actinic radiation transparent intermediate layer composite, comprising at least two polymer comprising composite layers lying on top of each other, wherein a second composite layer (C2) is an adhesion modulating layer arranged on top of the relief forming polymer layer and a first composite layer (C1) is a barrier layer for the diazonium compounds comprised in the recordable template layer (D) and positioned between the second composite layer (C2) and the recordable template layer (D),
(E2) optionally and preferably a protective film.

11. A method for the production of a semi-finished product of claim 10, said method comprising the following steps:
(i) Providing a protective or carrier film (E1),
(ii) Applying and drying a formulation for a recordable template layer (D) on one side,
(iii) Applying and drying a formulation for a barrier layer (C1) onto layer (D),
(iv) Applying and drying a formulation for an adhesion modulating layer (C2) onto the barrier layer (C1),
(v) optionally applying a protective layer (E2) onto the adhesion modulating layer (C2).

12. A method for the production of a recording element of claim 1 using a semi-finished product of claim 10 and a flexographic printing element comprising a carrier film (A), a relief forming polymer layer (B), optionally an adhesive layer between the relief forming polymer layer (B) and the carrier film (A) and optionally a peelable protective film or cover film (E3) on the relief forming polymer layer (B), said method comprising the following steps:
(i) removing optionally present protective films or cover films (E2), (E3) from the actinic radiation transparent intermediate layer compound (C) and from the relief forming polymer layer (B) of the flexographic printing element,
(ii) transferring and laminating the actinic radiation transparent intermediate layer composite (C) together with the recordable template layer (D) and the cover film (E1) onto the relief forming polymer layer (B) of the flexographic printing element.

13. A method for producing high-resolution flexographic printing plates by using a recording element of claim 1 and by imaging by means of digital information transmission using actinic laser radiation, said method comprising the following process steps:
(1) peeling off the cover film (E1),
(2) exposing the recordable template layer (D) by means of actinic laser radiation of 10 to 1500 mJ/cm2 in the spectral range of 330 nm to 430 nm, in particular 50 to 1000 mJ/cm2 in the specified spectral range, to form an exposed template layer,
(3) developing the exposed template layer to form an imaged template layer (D), in particular developing by using an alkaline solution or an alkaline vapor, in particular ammonia vapor,
(4) exposing the recording element provided with the imaged template layer (D) with actinic radiation through the imaged template layer (D), in particular with actinic radiation of >5 to 100 J/cm2 in a spectral range from 200 nm to 450 nm,
(5) removing the template layer (D) and the present intermediate layer composite (C) as well as the not polymerized portions of the relief-forming layer (B) to form the flexographic printing plate,
(6) drying the obtained flexographic printing plate and
(7) optionally and preferably after-treating the flexographic printing plate with UV light.

14. The method of claim 13, wherein the intermediate layer composite (C) is peeled off together with the template layer (D) and the not-polymerized portions of the relief forming polymer layer (B) are removed
by means of a washing out/leaching means that contains or consists of water and/or solvent, and/or
by means of a thermic method that achieves melting or evaporating by warming or heating.

15. The recording element of claim 2, wherein the actinic radiation transparent intermediate layer composite (C) has a thickness of from 0.4 μm to 30 μm and/or wherein the second composite layer (C2) of the intermediate layer composite (C) has a thickness of 0.2 μm to 15 μm and/or wherein the first composite layer (C1) of the intermediate layer composite (C) has a thickness of 0.2 μm to 15 μm.

16. The recording element of claim 3, wherein
the second composite layer (C2) of the intermediate layer composite (C) has a peeling force to the relief forming polymer layer (B) of 0.1 N/m to 100 N/m, and
an elongation of 200 to 1000.

17. The recording element of claim 4, wherein the first composite layer (C1) consists of at least 85% by weight of at least one binder which is based on at least one water-soluble and/or organic solvent-soluble polymer or copolymer and that has an oxygen permeability of less than 500 (cm³×100 μm)/(m²×d×bar), and/or
the second composite layer (C2) consists of at least 85% by weight of at least one binder which is based on at least one water-soluble and/or organic solvent-soluble soft elastic and/or thermoplastic polymer or copolymer.

18. The recording element of claim 5, wherein the binder of the first composite layer (C1) is selected from
saturated and unsaturated polyesters, like polyethylene terephthalate (PET), polybutylene terephthalate (PBT), polyethylene naphthalate (PEN), polymethylmethacrylate (PMMA), polylactic acid (PLA), and mixtures thereof, all with a molecular weight above 1000 and
the binder of the second composite layer (C2) is selected from
polyvinyl alcohol, polyvinyl pyrrolidone, polyamide, polyurethane, (silicone-polyurethane) copolymers, gelatine and mixtures thereof.

19. The recording element of claim 6, wherein the recordable template layer (D) has a layer thickness of from 3 μm to 30 μm and/or can be exposed with actinic laser radiation of a power of 50 to 1000 mJ/cm² in the spectral range from 330 nm to 430 nm.

20. The recording element of claim 7, wherein the recordable template layer can be developed by means of an alkaline solution or alkaline vapors, like ammonia vapor, such that the unexposed areas have an actinic density>3.0.

21. The recording element of claim 8, wherein the recordable template layer consists of at least 85% by weight of the mixture of the at least one cellulose ester-based binder and the diazonium compound and the reactive coupler compound and/or wherein the ratio of binder to diazo compound is from 20:1 to 1:1, and/or the ratio of diazo compound to coupler compound is from 2:1 to 1:2.

22. The recording element of claim 9, wherein the relief forming polymer layer (B) has a layer thickness of 300 μm to 6000 μm and/or comprises or consists of at least one elastomeric binder, at least two ethylenically unsaturated copolymerizable organic compounds (monomers) and at least one photoinitiator or a photoinitiator system.
